(19) United States
(12) Patent Application Publication
(10) Pub. No.: US 2016/0260904 A1
(43) Pub. Date: Sep. 8, 2016

(54) TRANSPARENT DISPLAY DEVICE AND METHOD OF MANUFACTURING THE SAME

(71) Applicant: Samsung Display Co., LTD., Yongin-City (KR)

(72) Inventors: Hye-Young PARK, Seongnam-si (KR); Seung-Ho JUNG, Hwaseong-si (KR)

(21) Appl. No.: 14/919,167

(22) Filed: Oct. 21, 2015

(30) Foreign Application Priority Data
Mar. 2, 2015 (KR) 10-2015-0028872

(51) Int. Cl. H01L 51/00; H01L 27/32; H01L 51/56; H01L 51/52

(52) U.S. Cl. CPC H01L 51/0043; H01L 51/5253; H01L 27/3246; H01L 51/5281; H01L 51/5206; H01L 51/56; H01L 2251/301; H01L 2251/5369; H01L 2251/5338; H01L 2227/323

(57) ABSTRACT

A transparent display device includes a polymer substrate including a pixel area and a transmission area, a color correction layer including a metal nano-pattern on the polymer substrate, a pixel circuit on the color correction layer, a first electrode connected to the pixel circuit, a display layer on the first electrode, and a second electrode facing the first electrode and covering the display layer.

This application claims priority to Korean Patent Applications No. 10-2015-0028872, filed on Mar. 2, 2015, and all the benefits accruing therefrom under 35 U.S.C. §119, the content of which in its entirety is hereby incorporated by reference.

### BACKGROUND

1. Field

Exemplary embodiments of the invention relate to display devices. More particularly, exemplary embodiments of the invention relate to transparent display devices including a transparent substrate and methods of manufacturing the same.

2. Discussion of Related Art

Recently, a display device having transparent or transmitting properties has been developed. A base substrate having the transparent or transmitting properties, for example, may be employed to achieve a transparent display device. When a transparent resin substrate is implemented as the base substrate, a flexible transparent display device that may be capable of being folded or bended may be realized.

### SUMMARY

A resin material or a polymer material of a transparent resin substrate may be chemically modified during a device process, thereby causing a deterioration of various properties of a base substrate or a display device.

Exemplary embodiments provide a display device having improved transmissive and mechanical properties.

Exemplary embodiments provide a method of manufacturing a transparent display device having improved transmissive and mechanical properties.

According to exemplary embodiments, a display device may include a polymer substrate including a pixel area and a transmission area, a color correction layer including a metal nano-pattern on the polymer substrate, a pixel circuit on the color correction layer, a first electrode connected to the pixel circuit, a display layer on the first electrode, and a second electrode facing the first electrode and covering the display layer.

In exemplary embodiments, the color correction layer may be provided by a block copolymer.

In exemplary embodiments, the color correction layer may correct a color of light transmitted from the polymer substrate.

In exemplary embodiments, the metal nano-pattern may include a periodic nano-pore array.

In exemplary embodiments, a width of each nano-pore included in the periodic nano-pore array may be about 30 nanometers (nm) to about 50 nm.

In exemplary embodiments, the metal nano pattern may include nano-cylinder structures substantially perpendicularly oriented to a surface of the polymer substrate.

In exemplary embodiments, the color correction layer may further include at least one of gold (Au), silver (Ag), platinum (Pt), palladium (Pd), iridium (Ir), osmium (Os), ruthenium (Ru), and rhodium (Rh).

In exemplary embodiments, the polymer substrate may further include a colored polymer material. In an exemplary embodiment, a surface plasmon resonance occurs in the metal nano-pattern such that the polymer substrate becomes substantially colorless and transparent.

In exemplary embodiments, the colored polymer material may include a polyimide-based material.

In exemplary embodiments, the transparent display device may further include a barrier layer is between the polymer substrate and the color correction layer.

In exemplary embodiments, the transparent display device may further include a barrier layer is between the color correction layer and the pixel circuit.

According to exemplary embodiments, a transparent display device may include a transparent flexible substrate including a pixel area and a transmission area, a color correction layer, which includes a metal nano-pore array, on the transparent flexible substrate, a barrier layer on the color correction layer, a pixel circuit selectively disposed on a portion of the barrier layer on the pixel area, a circuit insulation layer which at least partially covers the pixel circuit on the barrier layer, a via-insulation layer covering the pixel circuit on the circuit insulation layer, a first electrode on the via-insulation layer, the first electrode being electrically connected to the pixel circuit, a display layer on the first electrode, and a second electrode facing the first electrode and covering the display layer.

In exemplary embodiments, the transparent flexible substrate may include a colored polymer material. The color correction layer may be provided by a block copolymer.

In exemplary embodiments, the via-insulation layer may be disposed only on the pixel area.

In exemplary embodiments, the transparent display device may further include a pixel defining layer on the via-insulation layer. In an exemplary embodiment, the pixel defining layer may expose a top surface of the first electrode. In an exemplary embodiment, a transmitting window may be defined in the transmission area by sidewalls of the pixel defining layer and the via-insulation layer.

In exemplary embodiments, the circuit insulation layer may include a gate insulation layer and an insulating interlayer sequentially stacked on the barrier layer. The gate insulation layer and the insulating interlayer may extend commonly on the pixel area and the transmission area. A top surface of the insulating interlayer may be exposed by the transmitting window.

According to exemplary embodiments, a method of manufacturing a transparent display device may include forming a color correction layer having a metal nano-pore array on a colored polymer substrate, forming a pixel circuit on the color correction layer, forming an insulation structure covering the pixel circuit, and forming a display structure on the insulation structure such that the display structure is electrically connected to the pixel circuit.

In exemplary embodiments, a surface plasmon resonance may occur in the metal nano-pattern such that the colored polymer substrate becomes substantially colorless and transparent.

In exemplary embodiments, forming the color correction layer may include forming a metal thin film on the colored polymer substrate, forming a copolymer thin film on the metal thin film, micro-phase separating the copolymer thin film to a block copolymer including nano-cylinder structures substantially perpendicularly oriented to a surface of the colored polymer substrate, exposing the metal thin film by partially removing the block copolymer such that the metal thin film becomes the metal nano-pore array, etching exposed portions of the metal thin film, and removing remaining portions of the block copolymer on the metal thin film.

In exemplary embodiments, the block copolymer may include polystyrene-block-poly(methyl methacrylate) (PS-b-PMMA).

Therefore, the transparent display device and the method of manufacturing the same according to exemplary embodiments may use the colored polymer substrate as a based substrate of the transparent display device. The colored polymer substrate may have relatively superior heat resistance and durability such that mechanical property of the transparent display device may be improved. In addition, the color correction layer including the metal nano-pattern may be disposed on the polymer substrate so that a transparency of the colored polymer substrate may be improved. Thus, the transparency and the mechanical property of the transparent display device may be improved.

In addition, the metal nano-pattern may be provided by a simple process using the block copolymer such that additional materials for correcting the color of the polymer substrate may be not required. Thus, manufacturing cost for the transparent display device may be decreased and reliability of the transparent display device may be improved.

### BRIEF DESCRIPTION OF THE DRAWINGS

The above and other exemplary embodiments, advantages and features of this disclosure will become more apparent by describing in further detail exemplary embodiments thereof with reference to the accompanying drawings, in which:

FIG. 1 is a cross-sectional view illustrating exemplary embodiments of a transparent display device according to the invention.

FIG. 2A is a plan view illustrating an exemplary embodiment of a color correction layer included in the transparent display device of FIG. 1.

FIG. 2B is a plan view illustrating another exemplary embodiment of a color correction layer included in the transparent display device of FIG. 1.

FIGS. 3 to 9 are cross-sectional view illustrating exemplary embodiments of a method of manufacturing a transparent display device according to the invention.

FIG. 10 is a cross-sectional view illustrating exemplary embodiments of a transparent display device according to the invention.

FIG. 11 is a cross-sectional view illustrating exemplary embodiments of a transparent display device according to the invention.

FIG. 12 is a cross-sectional view illustrating exemplary embodiments of a transparent display device according to the invention.

### DETAILED DESCRIPTION OF EMBODIMENTS

Exemplary embodiments will be described more fully hereinafter with reference to the accompanying drawings, in which various embodiments are shown.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10%, 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

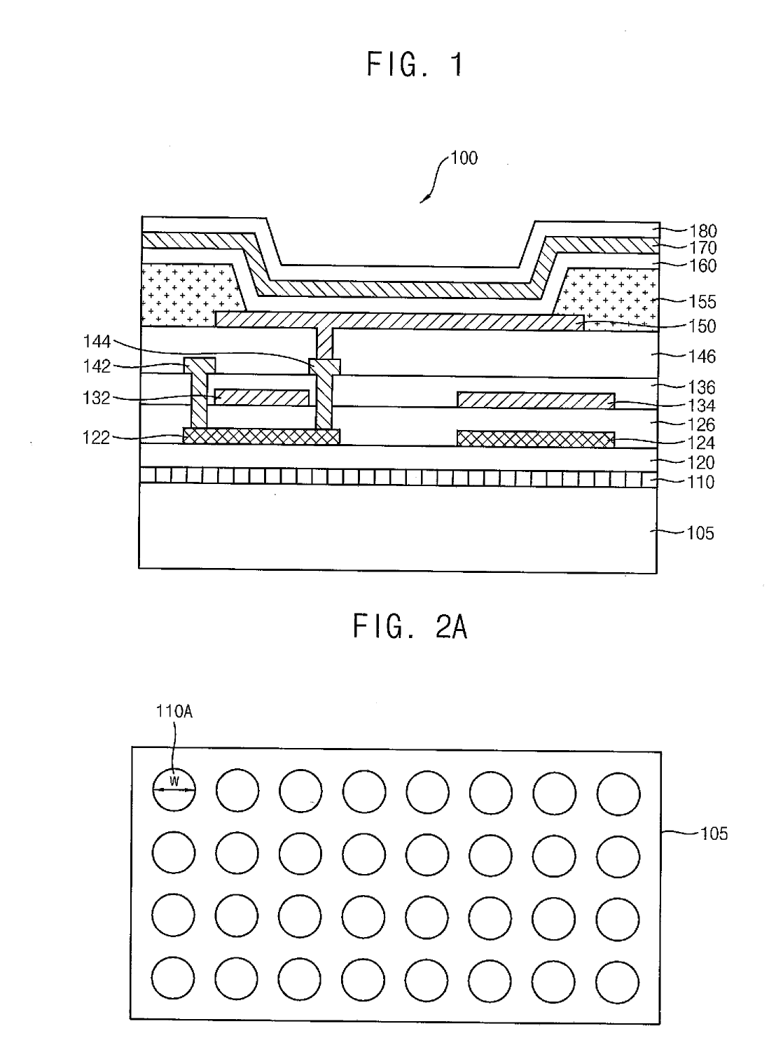

FIG. 1 is a cross-sectional view illustrating a transparent display device according to exemplary embodiments.

Referring to FIG. 1, the transparent display may include a polymer substrate 105, a color correction layer 110 disposed on the polymer substrate 105, a back plane (“BP”) structure disposed on the color correction layer 110, and a display structure stacked on the BP structure.

The polymer substrate 105 may be provided as a back plane substrate or a base substrate. A transparent insulation substrate may be used as the substrate 110. In an exemplary embodiment, a polymer-based substrate having transmissive and flexible properties may be utilized. Accordingly, the transparent display device may be provided as a transparent flexible display device. The polymer substrate 105 may include a pixel area and a transmission area.

In exemplary embodiments, the polymer substrate 105 may include a colored polymer material. In an exemplary embodiment, the polymer substrate 105 may include a substantially yellow polyimide-based material, for example.

In exemplary embodiments, a connecting group having a relatively small steric hindrance may be combined between imide nitrogens of imide units contained in the polyimide-based material. In exemplary embodiment, the connecting group may include an aromatic group such as unsubsituted benzene, for example.

A combination of the imide nitrogens and the connecting group may serve as an electron donor unit. A carbonyl group included in the imide unit and adjacent to the imide nitrogen may have a relatively low electron density, and thus may serve as an electron acceptor unit.

In this case, a charge transfer complex (“CTC”) between neighboring polymer chains may be provided by an intermolecular interaction between the electron donor unit and the electron acceptor unit. Accordingly, a heat resistance and a mechanical stability of the polymer substrate 105 may be enhanced. In an exemplary embodiment, a wavelength in a range of a visible light in a range of about 560 nanometers (nm) to about 580 nm may be absorbed by the CTC, for example. Thus, the substrate 110 may be transformed into the colored polymer substrate having a yellow color, for example.

The color correction layer 110 may be disposed on the polymer substrate 105. The color correction layer 110 may include a metal nano-pattern having periodicity. In exemplary embodiments, the color correction layer 110 may be provided by a block copolymer. The block copolymer may be micro-phase separated by self-assembly properties such that the metal nano-pattern may have the periodicity and various nano-patterns. The color correction layer 110 may correct a color of the polymer substrate 105 to become substantially colorless and transparent.

In exemplary embodiments, the metal nano-pattern may be a periodic nano-pore array. In an exemplary embodiment, the color correction layer 110 may include a metal pattern that has a plurality of nano-pores substantially regularly ordered. In exemplary embodiments, the metal nano-pattern may include a nano-cylinder structure substantially perpendicularly oriented to a surface of the polymer substrate 105, for example. In an exemplary embodiment, a width (or diameter) of a nano-pore may be about 30 nm to about 50 nm, for example. In exemplary embodiments, shapes of the nano-pores may be a circle, an ellipse, a square, etc., for example. In exemplary embodiments, the metal nano-pattern may include a nano-dot array, for example.

The color correction layer 110 may be provided by a noble metal. In exemplary embodiments, the color correction layer 110 may include at least one of gold (Au), silver (Ag), platinum (Pt), palladium (Pd), iridium (Ir), osmium (Os), ruthenium (Ru), and rhodium (Rh), for example. The above-described elements may be used alone or in any combination thereof.

A surface plasmon resonance may occur in the metal nano-pattern (e.g., the nano-pore array) such that the polymer substrate 105 becomes transparent. The surface plasmon resonance may occur at a surface of a metal thin film of the color correction layer 110 and transmit a specific wavelength rage of light, so that yellowish image by through the colored polymer substrate 105 may be corrected. In an exemplary embodiment, when the nano-pore array is disposed on the polymer substrate 105 including the substantially yellow polyimide-based material, the width of the nano-pore may be adjusted to transmit a substantially blue color light, for example. The yellow polymer substrate 105 and the blue color light may be mixed optically and additively so that the polymer substrate 105 (i.e., an image output from the transparent display device 100) may be substantially transformed entirely into a white or a transparent substrate. In the exemplary embodiment, the width of each nano-pore may be about 30 nm to about 50 nm, for example.

The BP structure including a pixel circuit and an insulation structure may be disposed on the color correction layer 110. In an exemplary embodiment, the pixel circuit may include a thin film transistor (“TFT”) and a wiring structure, for example. In an exemplary embodiment, the insulation structure may include a barrier layer 120, a gate insulation layer 126, an insulating interlayer 136 and a via-insulation layer 146 sequentially stacked on the polymer substrate 105 or the color correction layer 110, for example.

In exemplary embodiments, the barrier layer 120 may be disposed on the color correction layer 110. A diffusion of impurities or moistures between the polymer substrate 105 and structures thereon may be blocked by the barrier layer 120. The barrier layer 120 may have a multi-stacked structure including a silicon oxide layer and a silicon nitride layer that may be alternately and repeatedly provided.

In exemplary embodiments, a buffer layer may be further disposed on the barrier layer 120. The buffer layer may have a multi-stacked structure including a silicon oxide layer and a silicon nitride layer.

An active pattern may be disposed on the barrier layer 120. In exemplary embodiments, the active pattern may include a first active pattern 122 and a second active pattern 124.

The active pattern may include a silicon-based compound such as polysilicon. In exemplary embodiments, a source region and a drain region including p-type or n-type impurities may be provided at both ends of the first active pattern 122.

In exemplary embodiments, the active pattern may include a semiconductor oxide, e.g., indium gallium zinc oxide (“IGZO”), zinc tin oxide (“ZTO”), or indium tin zinc oxide (“ITZO”).

As illustrated in FIG. 1, the first and second active patterns 122 and 124 may be disposed (e.g., located) on the same layer, or substantially the same level or the same plane.

The gate insulation layer 126 may be disposed on the barrier layer 120 to cover the active patterns. The gate insulation layer 126 may include silicon oxide or silicon nitride. In exemplary embodiments, the gate insulation layer 126 may have a multi-stacked structure including a silicon oxide layer and a silicon nitride layer, for example.

A gate electrode may be disposed on the gate insulation layer 126. In exemplary embodiments, the gate electrode may include a first gate electrode 132 and a second gate electrode 134. The first gate electrode 132 and the second gate electrode 134 may be substantially superimposed over the first active pattern 122 and the second active pattern 124, respectively. The first and second gate electrodes 132 and 134 may be located on substantially the same level or the same plane.

In an exemplary embodiment, the gate electrode may include a metal such as aluminum (Al), silver (Ag), tungsten (W), copper (Cu), nickel (Ni), chrome (Cr), molybdenum (Mo), titanium (Ti), platinum (Pt), tantalum (Ta), neodymium (Nd) or scandium (Sc), an alloy of the metals, or a nitride of the metal. The above-described elements may be used alone or in any combination thereof. In exemplary embodiments, the gate electrode may have a multi-layered structure including Al and Mo, or Ti and Cu for reducing an electrical resistance, for example.

The insulating interlayer 136 may be disposed on the gate insulation layer 126 to cover the gate electrodes 132 and 134. In an exemplary embodiment, the insulating interlayer 136 may include silicon oxide or silicon nitride, for example. In exemplary embodiments, the insulating interlayer 136 may have a multi-stacked structure including a silicon oxide layer and a silicon nitride layer.

A source electrode 142 and a drain electrode 144 may extend through the insulating interlayer 136 and the gate insulation layer 126 to be in contact with the first active pattern 122. In an exemplary embodiment, the source and drain electrodes 142 and 144 may include a metal such as Al, Ag, W, Cu, Ni, Cr, Mo, Ti, Pt, Ta, Nd or Sc, an alloy of the metals or a nitride of the metal. The above-described elements may be used alone or in any combination thereof. In an exemplary embodiment, the source and drain electrodes 142 and 144 may have a multi-layered structure including different metals such as Al and Mo, for example.

The source electrode 142 and the drain electrode 144 may be in contact with the source region and the drain region of the first active pattern 122, respectively.

The TFT may be defined by the first active pattern 122, the gate insulation layer 126, the first gate electrode 132, the source electrode 142 and the drain electrode 144. Additionally, a capacitor may be defined by the second active pattern 124, the gate insulation layer 126 and the second gate electrode 134.

The wiring structure may include a data line and a scan line. A plurality of the data lines and the scan lines may cross each other, and each pixel may be defined at each intersection region of the data lines and the scan lines. However, the invention is not limited thereto, and each pixel may not be defined at each intersection region of the data lines and the scan lines. In an exemplary embodiment, the data line may be electrically connected to the source electrode 142, and the scan line may be electrically connected to the first gate electrode 132, for example. In exemplary embodiments, the wiring structure may further include a power line that may be parallel to the data line, for example. The capacitor may be electrically connected to the power line and the TFT.

The via-insulation layer 146 may be disposed on the insulating interlayer 136 to cover the source and drain electrodes 142 and 144. The via-insulation layer 146 may substantially serve as a planarization layer. In an exemplary embodiment, the via-insulation layer 146 may include an organic material such as polyimide, an epoxy-based resin, an acryl-based resin or polyester.

The display structure may be stacked on the via-insulation layer 146. In exemplary embodiments, the display structure may include a first electrode 150, a display layer 160 and a second electrode 170 sequentially stacked on the via-insulation layer 146.

The first electrode 150 may be disposed on the via-insulation layer 146. The first electrode 150 may include a via-portion that may extend through the via-insulation layer 146 to be electrically connected to the drain electrode 144.

In exemplary embodiments, the first electrode 150 may serve as a pixel electrode, and may be provided per each pixel. In an exemplary embodiment, the first electrode 150 may serve as an anode of the transparent display device.

In exemplary embodiments, the first electrode 150 may serve as a reflective electrode. In the exemplary embodiment, the first electrode 150 may include a metal such as Al, Ag, W, Cu, Ni, Cr, Mo, Ti, Pt, Ta, Nd or Sc, or an alloy of the metals. In an exemplary embodiment, the transparent display device 100 may be a top emission type generating an image toward the second electrode 170, for example.

In exemplary embodiments, the first electrode 150 may include a transparent conductive material having a high work function. In an exemplary embodiment, the first electrode 150 may include indium tin oxide (“ITO”), indium zinc oxide (“IZO”), zinc oxide or indium oxide, for example.

In exemplary embodiments, the first electrode 150 may have a multi-layered structure including the transparent conductive material and the metal.

A pixel defining layer (“PDL”) 155 may be disposed on the via-insulation layer 146, and may cover a peripheral portion of the first electrode 150. In an exemplary embodiment, the PDL 155 may include a transparent organic material such as a polyimide-based resin or an acryl-based resin. An area of the first electrode 150 that is not covered by the PDL 155 may be substantially equal to an area of an emission region in the each pixel.

The display layer 160 may be disposed on the PDL 155 and the first electrode 150. The display layer 160 may include an organic emitting layer that may be individually patterned for each of a red pixel (Pr), a green pixel (Pg) and a blue pixel (Pb) to generate a different color of light in the each pixel. The organic emitting layer may include a host material excited by a hole or an electron, and a dopant material for improving an emitting efficiency through absorbing and releasing an energy.

In exemplary embodiments, the display layer 160 may further include a hole transport layer (“HTL”) interposed between the first electrode 150 and the organic emitting layer. The display layer 160 may further include an electron transport layer (“ETL”) interposed between the second electrode 170 and the organic emitting layer.

In an exemplary embodiment, the HTL may include a hole transport material, e.g., 4,4′-bis[N-(1-naphtyl)-N-phenylamino]biphenyl (NPB), 4,4′-bis[N-(3-methylphenyl)-N-phenylamino]biphenyl (TPD), N,N′-di-1-naphtyl-N,N′-diphenyl-1,1′-biphenyl-4,4′-diamine (NPD), N-phenylcarbazole, polyvinylcarbazole, or any combination thereof.

In an exemplary embodiment, the ETL may include an electron transport material, e.g., tris(8-quinolinolato)aluminum (Alq3), 2-(4-iphenylyl)-5-4-tert-butylphenyl-1,3,4-oxadiazole (PBD), bis(2-methyl-8-quinolinolato)-4-phenylphenolato-aluminum (BAlq), bathocuproine (BCP), triazole (TAZ), phenylquinozaline, or any combination thereof.

In exemplary embodiments, the display layer 160 may include a liquid crystal layer instead of the organic light emitting layer. In the exemplary embodiment, the transparent display device may be provided as a liquid crystal display (“LCD”) device.

The display layer 160 may extend according to surfaces of the PDL 155 and the first electrode 150 as illustrated in FIG. 1. In exemplary embodiments, the display layer 160 may be confined by sidewalls of the PDL 155 to be individually provided in the each pixel.

The second electrode 170 may be disposed on the PDL 155 and the display layer 160. In exemplary embodiments, the second electrode 170 may serve as a common electrode provided on a plurality of the pixels. The second electrode 170 may face the first electrode 150 and may serve as a cathode of the transparent display device.

In an exemplary embodiment, the second electrode 170 may include a metal having a low work function such as Al, Ag, W, Cu, Ni, Cr, Mo, Ti, Pt, Ta, Nd or Sc, or an alloy of the metals.

An encapsulation layer 180 protecting the display structure may be disposed on the second electrode 170. In an exemplary embodiment, the encapsulation layer 180 may include an inorganic material such as silicon nitride and/or a metal oxide, for example.

In exemplary embodiments, a capping layer may be interposed between the second electrode 170 and the encapsulation layer 180. In an exemplary embodiment, the capping layer may include an organic material such as a polyimide resin, an epoxy resin or an acryl resin, or an inorganic material such as silicon oxide, silicon nitride or silicon oxynitride.

As described above, the transparent display device 100 may include the colored polymer substrate 105 as a base substrate. The colored polymer substrate 105 may have relatively superior heat resistance and durability such that mechanical property of the transparent display device 100 may be improved. In addition, the color correction layer 110 including the nano-pore array may be disposed on the polymer substrate 105 so that a transparency of the colored polymer substrate may be improved. Thus, the transparency and the mechanical property of the transparent display device 100 may be improved. Further, additional materials for correcting the color of the polymer substrate may be not required.

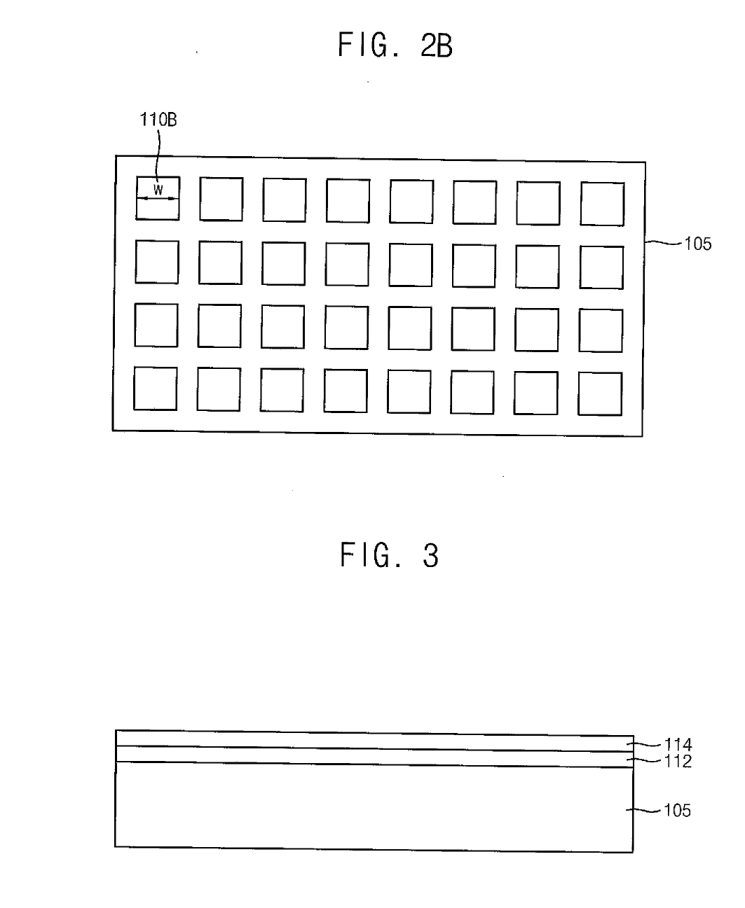

FIG. 2A is a plan view illustrating an exemplary embodiment of a color correction layer included in the transparent display device of FIG. 1. FIG. 2B is a plan view illustrating another exemplary embodiment of a color correction layer included in the transparent display device of FIG. 1.

Referring to FIGS. 2A and 2B, the color correction layer may be disposed on the polymer substrate 105. The color correction layer may include a metal nano-pore array.

In exemplary embodiments, as illustrated in FIG. 2A, a cross section of a nano-pore 110A may be a circle. In an exemplary embodiment, the nano-pore 110A may have a cylinder form or hemispherical form. In an exemplary embodiment, the width (diameter) W of the nano-pore 110A may be about 10 nm to about 50 nm, for example.

In exemplary embodiments, as illustrated in FIG. 2B, the cross section of a nano-pore 110B may be a square. The nano-pore 110B may have the cylinder form. In an exemplary embodiment, the width W of the nano-pore 110A may be about 10 nm to about 50 nm, for example.

Since the shapes of the nano-pores are examples, the cross sections of the nano-pores are not limited thereto. In an exemplary embodiment, the cross sections of the nano-pores may be ellipses, triangles, etc., for example.

The surface plasmon resonance may occur at the metal nano-pattern array such that a specific wavelength rage of light may be transmitted. In an exemplary embodiment, the yellow polymer substrate 105 and the blue color light may be mixed optically and additively so that the transparency of the polymer substrate 105 may be improved, for example.

FIGS. 3 to 9 are cross-sectional view illustrating a method of manufacturing a transparent display device according to exemplary embodiments.

Referring to FIGS. 3 to 9, a color correction layer 110 including a metal nano-pore array may be disposed on a polymer substrate 105.

As illustrated in FIG. 3, a metal thin film 112 may be disposed on the polymer substrate 105 and a copolymer thin film 114 may be disposed on the metal thin film 112.

In exemplary embodiments, the metal thin film 114 may be deposited on the polymer substrate 105 by a sputtering process to have substantially uniform thickness. In an exemplary embodiment, the metal thin film 112 may include at least one of Au, Ag, Pt, Pd, Ir, Os, Ru, and Rh, for example. Since these are exemplary embodiments, the metals included in the metal thin film 112 are not limited thereto.

The copolymer thin film 114 may be disposed on the metal thin film 112. In exemplary embodiments, the copolymer thin film 114 may be deposited on the metal thin film 112 by a spin coating process. In exemplary embodiments, the copolymer thin film 114 may include a combination of polystyrene (“PS”) and poly methyl methacrylate (“PMMA”). In an exemplary embodiment, to form a PS-b-PMMA that is a block copolymer, a PS-r(random)-PMMA may be deposited on the metal thin film 112, for example. Since this is an exemplary embodiment, configuration of the copolymer is not limited thereto.

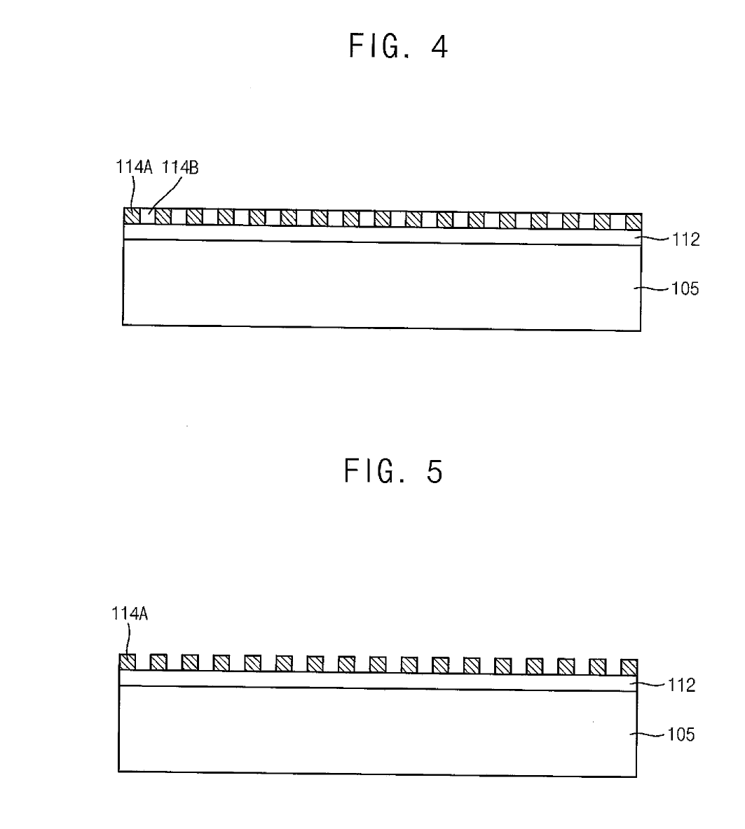

As illustrated in FIG. 4, the copolymer thin film 114 may be micro-phase separated to the block copolymer 114A and 114B including nano-cylinder structures substantially perpendicularly oriented to a surface of the polymer substrate 105. In exemplary embodiments, the copolymer thin film 114 may obtain a perpendicular orientation of the micro-phases of the PS-b-PMMA 114A and 114B by an annealing process. Thermal annealing or solvent annealing the copolymer thin film 114 may be performed to obtain the block copolymer. Since this is an exemplary embodiment, obtaining method of the block copolymer is not limited thereto. In an exemplary embodiment, the block copolymer may be generated by using an electric field, a grafoepitaxy, etc., for example.

The block copolymer may have the cylinder form substantially perpendicularly oriented to the surface of the polymer substrate 105 or a sphere form.

As illustrated in FIG. 5, portions of the block copolymer may be removed to partially expose the metal thin film 112 such that the metal thin film 112 may become a metal nano-pore array. The block copolymer may be partially etched or exposed from an ultraviolet ray such that the block copolymer may have the nano-pore array. In exemplary embodiment, the PS (or PMMA) 114B may be removed by a wet etching, and the metal thin film 112 under the PS (or PMMA) 114B may be exposed. In exemplary embodiments, PS (or PMMA) 114B may be removed by the ultraviolet ray exposure, and the metal thin film 112 under the PS (or PMMA) 114B may be exposed. Thus, the block copolymer may have the nano-pore array.

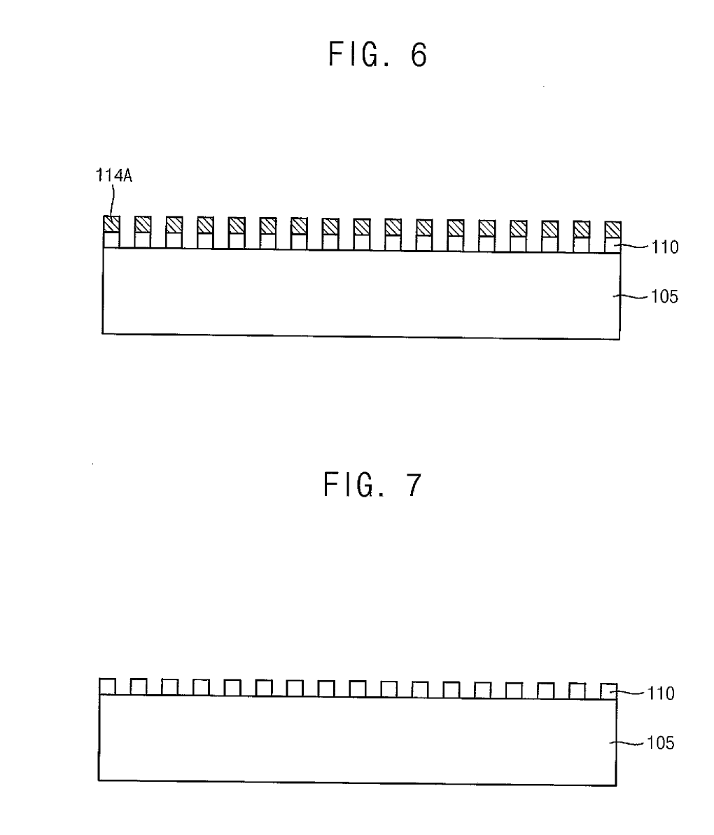

As illustrated in FIG. 6, the exposed metal thin film 110 may be etched. In an exemplary embodiment, the exposed metal thin film 110 may be removed by a dry etching or the wet etching, for example.

As illustrated in FIG. 7, remaining portions of the block copolymer on the metal thin film 112 may be removed. In an exemplary embodiment, the block copolymer may be removed by the wet etching or an ashing, for example. The remaining portions of the block copolymer may be the PMMA (or PS) 114A. Thus, the color correction layer 110 including the metal nano-pore array may be disposed on the polymer substrate 105.

Accordingly, the metal nano-pore array may be disposed on the polymer substrate 110 by the block copolymer. The width of the nano-pores may be adjusted so that a wavelength rage of light transmitting the color correction layer 110 may be determined. In exemplary embodiments, the color correction layer 110 on the yellow polymer substrate 105 may include the nano-pore array for transmitting a blue color light. A surface plasmon resonance occurs in the metal nano-pore array such that the polymer substrate 105 may become substantially colorless and transparent. In an exemplary embodiment, the yellow polymer substrate 105 and the blue color light may be mixed optically and additively so that the transparency of the polymer substrate 105 may be improved, for example.

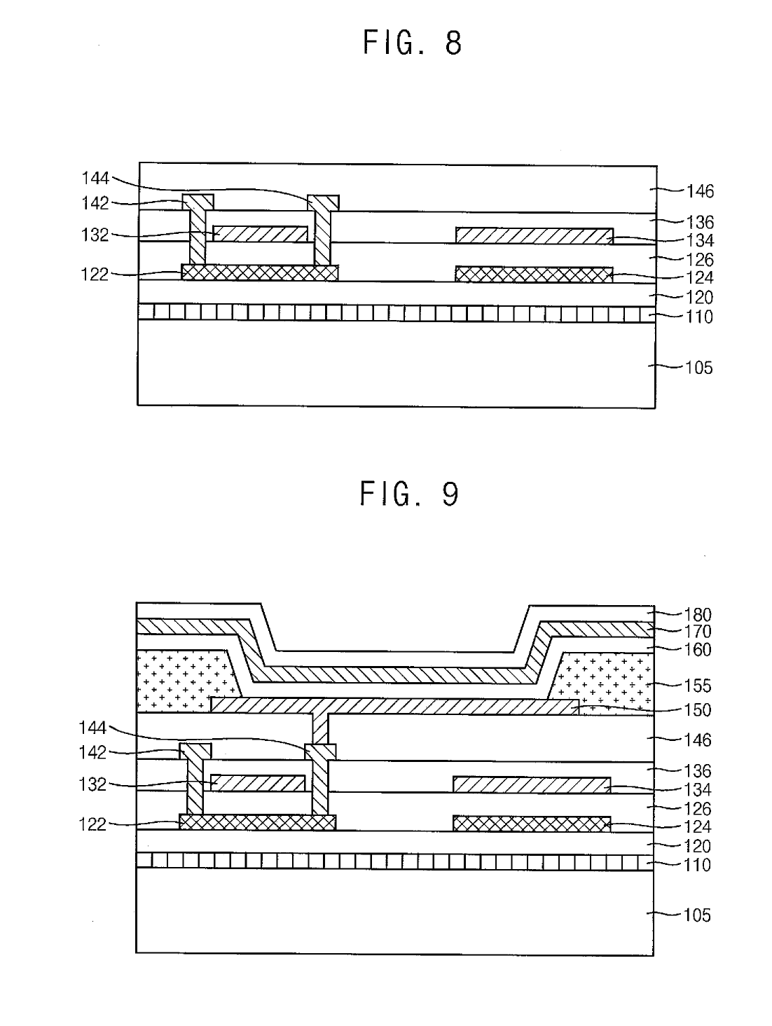

Referring to FIG. 8, a BP structure including a pixel circuit and an insulation structure may be disposed on the polymer substrate 105 and the color correction layer 110.

In exemplary embodiments, a barrier layer 120 may be disposed on the color correction layer 110. The barrier layer 120 may be provided by repeatedly depositing silicon oxide and silicon nitride.

First and second active patterns 122 and 124 may be disposed on the barrier layer 120.

In exemplary embodiments, a semiconductor layer may be disposed on the barrier layer 120 using amorphous silicon or polysilicon, and then may be patterned to form the first and second active patterns 122 and 124.

In exemplary embodiments, a crystallization process, e.g., a low temperature polycrystalline silicon (“LTPS”) process or a laser crystallization process, may be further performed after the formation of the semiconductor layer. As described above, the substrate 110 may include the colored polymer substrate having the improved heat resistance and mechanical property by the CTC. Thus, flexible and mechanical properties of the substrate 110 may be maintained even after the crystallization process.

In exemplary embodiments, the semiconductor layer may include a semiconductor oxide such as IGZO, ZTO or ITZO, for example.

A gate insulation layer 126 covering the active patterns 122 and 124 may be disposed on the barrier layer 120, and gate electrodes 132 and 134 may be disposed on the gate insulation layer 126.

The gate insulation layer 126 may be provided by solely or repeatedly depositing silicon oxide and silicon nitride.

In an exemplary embodiment, a first conductive layer may be disposed on the gate insulation layer 126, and may be etched by a photolithography process, for example, to form a first gate electrode 132 and a second gate electrode 134. The first gate electrode 132 and the second gate electrode 134 may substantially overlap the first active pattern 122 and the second active pattern 124, respectively, with respect to the gate insulation layer 126.

The first conductive layer may be provided using a metal, an alloy or a metal nitride. The first conductive layer may be provided by depositing a plurality of metal layers.

The gate electrodes 132 and 134 may be provided simultaneously with a scan line. In an exemplary embodiment, the gate electrodes 132 and 134, and the scan line may be provided from the first conductive layer by substantially the same etching process, for example. The scan line may be integrally connected to the first gate electrode 132.

In exemplary embodiments, impurities may be implanted into the first active pattern 122 using the first gate electrode 132 as an ion-implantation mask such that a source region and a drain region may be provided at both ends of the first active pattern 122. A portion of the first active pattern 122 between the source and drain regions may serve as a channel region substantially overlapping the first gate electrode 132.

An insulating interlayer 136 covering the gate electrodes 132 and 134 may be disposed on the gate insulation layer 126. A source electrode 142 and a drain electrode 144 may be provided through the insulating interlayer 136 and the gate insulation layer 126 to be in contact with the first active pattern 122.

In an exemplary embodiment, the insulating interlayer 136 and the gate insulation layer 126 may be partially etched to form contact holes through which the first active pattern 122 may be partially exposed, for example. A second conductive layer filling the contact holes may be disposed on the insulating interlayer 136, and then may be patterned by a photolithography process to form the source electrode 142 and the drain electrode 144.

In exemplary embodiments, the source electrode 142 and the drain electrode 144 may be in contact with the source region and the drain region, respectively. The source electrode 142 may be integrally connected to a data line. In the exemplary embodiment, the source electrode 142, the drain electrode 144 and the data line may be provided from the second conductive layer by substantially the same etching process.

The insulating interlayer 136 may be provided by depositing silicon oxide and/or silicon nitride. The second conductive layer may be provided using a metal, an alloy or a metal nitride. The second conductive layer may be provided by depositing a plurality of metal layers.

By performing the above-mentioned processes, a TFT including the source electrode 142, the drain electrode 144, the gate electrode 132, the gate insulation layer 126 and the first active pattern 122 may be disposed on the polymer substrate 105 (and the color correction layer 110). A capacitor including the second active pattern 124, the gate insulation layer 126 and the second gate electrode 134 may be also provided. Accordingly, the pixel circuit including the data line, the scan line, the TFT and the capacitor may be disposed on the substrate 110.

Subsequently, a via-insulation layer 146 covering the source electrode 142 and the drain electrode 144 may be disposed on the insulating interlayer 136.

In an exemplary embodiment, the via-insulation layer 146 may be provided using a transparent organic material such as polyimide, an epoxy-based resin, an acryl-based resin or polyester, for example. The via-insulation layer 146 may have a sufficient thickness to have a substantially leveled or planar top surface.

In an exemplary embodiment, the barrier layer 120, the semiconductor layer, the first and second conductive layers, the gate insulation layer 126, the insulating interlayer 136 and the via-insulation layer 146 may be provided by at least one of a chemical vapor deposition (“CVD”) process, a plasma enhanced chemical vapor deposition (“PECVD”) process, a high density plasma-chemical vapor deposition (“HDP-CVD”) process, a thermal evaporation process, a vacuum deposition process, a spin coating process, a sputtering process, an atomic layer deposition (“ALD”) process and a printing process, for example.

Referring to FIG. 9, the display structure may be disposed on the BP structure.

In exemplary embodiments, a first electrode 150 electrically connected to the TFT may be disposed. In an exemplary embodiment, the via-insulation layer 146 may be partially etched to form a via hole through which the drain electrode 144 may be exposed, for example. A third conductive layer sufficiently filling the via hole may be disposed on the via-insulation layer 146 and the drain electrode 144, and then may be patterned to form the first electrode 150.

In an exemplary embodiment, the third conductive layer may be provided using a metal such as Al, Ag, W, Cu, Ni, Cr, Mo, Ti, Pt, Ta, Nd or Sc, or an alloy of the metals by a thermal evaporation process, a vacuum deposition process, a sputtering process, an ALD process, a CVD process, a printing process, etc., for example. In exemplary embodiments, the third conductive layer may be provided using a transparent conductive material such as ITO, IZO, zinc oxide or indium oxide.

A PDL 155 may be disposed on the via-insulation layer 146. The PDL 155 may cover a peripheral portion of the first electrode 150. In an exemplary embodiment, a photosensitive organic material such as a polyimide resin or an acryl resin may be coated, and then exposure and developing processes may be performed to form the PDL 155, for example.

A display layer 160 may be disposed on the PDL 155 and the first electrode 150.

The display layer 160 may be provided using an organic light emitting material for generating a red color of light, a blue color of light or a green color of light. In an exemplary embodiment, the display layer 160 may be provided by a spin coating process, a roll printing process, a nozzle printing process, an inkjet process, etc., using a fine metal mask (“FMM”) that may include an opening through which a region corresponding to a red pixel, a green pixel, or a blue pixel is exposed, for example. Accordingly, an organic emitting layer including the organic light emitting material may be individually provided in each pixel.

In exemplary embodiments, an HTL may be provided before the formation of the organic emitting layer using the above-mentioned hole transport material. An ETL may be also disposed on the organic emitting layer using the above-mentioned electron transport material. The HTL and the ETL may be disposed according to surfaces of the PDL 155 and the first electrode 150 to be provided commonly on a plurality of pixels. Alternatively, the ETL or the ETL may be patterned per each pixel by processes substantially the same as or similar to those for the organic emitting layer.

In an exemplary embodiment, a metal having a low work function such as Al, Ag, W, Cu, Ni, Cr, Mo, Ti, Pt, Ta, Nd or Sc, or an alloy of the metals may be deposited on the display layer 160 to form a second electrode 170. In an exemplary embodiment, a mask including an opening through which a plurality of the pixels is commonly exposed may be used to deposit the metal for the formation of the second electrode 170, for example.

An encapsulation layer 180 may be disposed on the second electrode 170. In an exemplary embodiment, the encapsulation layer 180 may be provided by depositing an inorganic material such as silicon nitride and/or a metal oxide, for example. In exemplary embodiments, a capping layer may be further disposed between the second electrode 170 and the encapsulation layer 180 using an organic material such as a polyimide resin, an epoxy resin or an acryl resin, or an inorganic material such as silicon oxide, silicon nitride or silicon oxynitride.

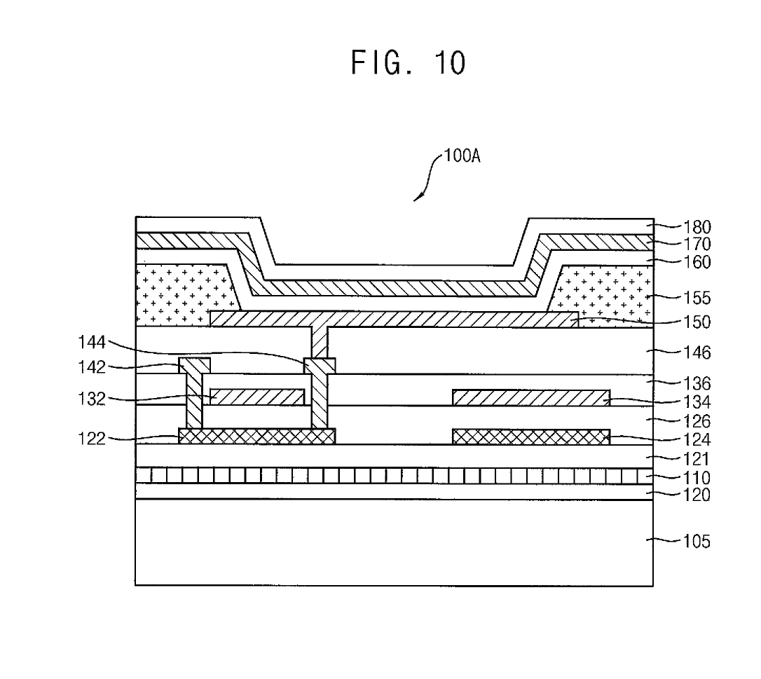

FIG. 10 is a cross-sectional view illustrating a transparent display device according to exemplary embodiments.

The transparent display device of the exemplary embodiments is may have elements and/or constructions substantially the same as or similar to the transparent display device explained with reference to FIG. 1 except for disposition of a color correction layer. Thus, the same reference numerals will be used to refer to the same or like parts as those described in the exemplary embodiments of FIG. 1, and any repetitive explanation concerning the above elements will be omitted.

Referring to FIG. 10, the transparent display device 100A may include a barrier layer 120 between a polymer substrate 105 and a color correction layer 110.

In exemplary embodiments, the barrier layer 120 may be disposed on the polymer substrate 105, the color correction layer 110 may be disposed on the barrier layer 120, and a buffer layer 121 may be disposed on the color correction layer 110.

Accordingly, as described above, a substantially yellow polymer substrate 105 and a blue color light transmitted by the color correction layer 110 may be mixed optically and additively so that the polymer substrate 105 may be substantially transformed entirely into a white or a transparent substrate.

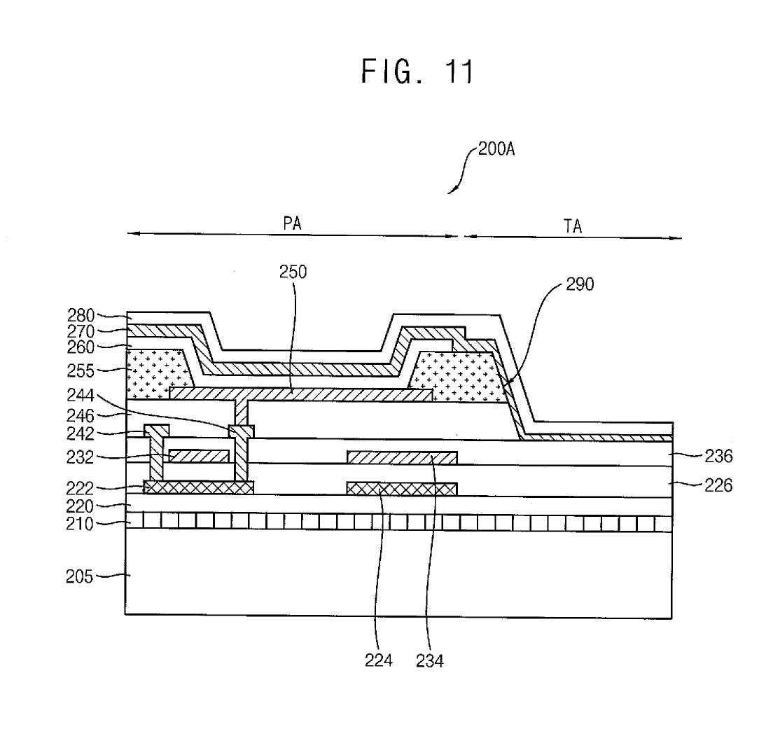

FIG. 11 is a cross-sectional view illustrating a transparent display device according to exemplary embodiments.

The transparent display device of FIG. 11 is may have elements and/or constructions substantially the same as or similar to the transparent display device explained with reference to FIG. 1 except for an addition of a transmission area. Thus, the same reference numerals will be used to refer to the same or like parts as those described in the exemplary embodiments of FIG. 1, and any repetitive explanation concerning the above elements will be omitted.

Referring to FIG. 11, the transparent display device 200A may include a pixel area PA and a transmission area TA.

A red pixel, a green pixel and a blue pixel may be alternately arranged in the pixel area PA. The transmission area TA may extend to be laterally adjacent to the pixels.

As illustrated in FIG. 1, the polymer substrate 205 may include a colored polymer substrate having a substantially yellow color.

A color correction layer 210 may be disposed on the polymer substrate 105.

The color correction layer 110 may include a metal nano-pore array. In exemplary embodiments, the color correction layer 210 may be provided by a block copolymer. The color correction layer 210 may correct a color of the polymer substrate to become substantially colorless and transparent.

A pixel circuit and an insulation structure may be disposed on the polymer substrate 205 of the pixel area PA. As illustrated with reference to FIG. 1, the pixel circuit may include a TFT, a capacitor and a wiring structure.

The TFT may include a first active pattern 222, a gate insulation layer 226, a first gate electrode 232, a source electrode 242 and a drain electrode 244. The capacitor may include a second active pattern 224, the gate insulation layer 226 and the second gate electrode 234.

The insulation structure may include a barrier layer 220, the gate insulation layer 226, an insulating interlayer 236 and a via-insulation layer 246 sequentially stacked on the substrate 210.

In exemplary embodiments, the barrier layer 220, the gate insulation layer 226 and the insulating interlayer 236 among the insulation structure may be provided commonly on the pixel area PA and the transmission area TA. The via-insulation layer 246 among the insulation structure may be substantially removed on the transmission area TA. Thus, the via-insulation layer 246 may be substantially only on the pixel area PA.

A display structure may be stacked on the via-insulation layer 246. As illustrated with reference to FIG. 1, the display structure may include a first electrode 250, a display layer 260 and a second electrode 270 sequentially stacked on the via-insulation layer 246. A PDL 255 may be disposed selectively on the pixel area PA to at least partially expose the first electrode 250.

A transmitting window 290 may be defined in the transmission area TA. In exemplary embodiments, a top surface of the insulating interlayer 236 may be exposed through the transmitting window 290. In the exemplary embodiment, the transmitting window 290 may be defined by sidewalls of the PDL 255 and the via-insulation layer 246, and the top surface of the insulating interlayer 236.

As illustrated in FIG. 11, the second electrode 270 may be commonly and continuously disposed on the pixel area PA and the transmission area TA. In the exemplary embodiment, the second electrode 270 may extend according to surfaces of the display layer 260 and the PDL 255, and a sidewall and a bottom of the transmitting window 290.

In exemplary embodiments, a portion of the second electrode 270 on the transmission area TA may have a thickness smaller than that of a portion of the second electrode 270 on the pixel area PA. Accordingly, a transparency or a transmittance in the transmission area TA may be improved.

An encapsulation layer 280 may be disposed on the second electrode 270, and may commonly cover the pixel area PA and the transmission area TA.

According to exemplary embodiments described above, the polymer substrate 205 may be substantially transparent by the color correction layer 210. Therefore, even though the barrier layer 220, the gate insulation layer 226 and the insulating interlayer 236 are not removed on the transmission area TA, a predetermined transmittance or transparency of the transparent display device may be achieved.

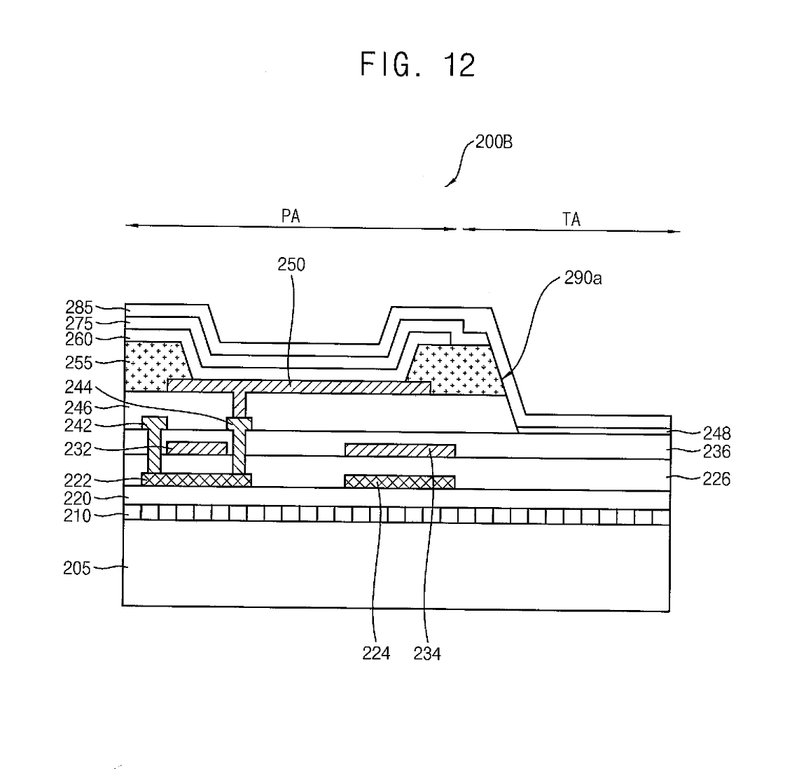

FIG. 12 is a cross-sectional view illustrating a transparent display device according to exemplary embodiments.

The transparent display device of FIG. 12 is may have elements and/or constructions substantially the same as or similar to the transparent display device explained with reference to FIG. 11 except for a structure of a transmission area. Thus, the same reference numerals will be used to refer to the same or like parts as those described in the exemplary embodiments of FIG. 11, and any repetitive explanation concerning the above elements will be omitted.

Referring to FIG. 12, the transparent display device may include a pixel area PA and a transmission area TA. A transmitting window 290a may be defined in the transmission area TA. The transmitting window 290a may be defined by sidewalls of a PDL 255 and a via-insulation layer 246, and a top surface of an insulating interlayer 236.

A color correction layer 210 may be disposed on the polymer substrate 205. The color correction layer 210 may include a metal nano-pattern having periodicity. In exemplary embodiments, the color correction layer 210 may be provided by a block copolymer. The color correction layer 210 may correct a color of the polymer substrate 205 to become substantially colorless and transparent.

In exemplary embodiments, the second electrode 275 may be selectively disposed only on the pixel area PA, and may not extend on the transmission area TA. Accordingly, a transparency or a transmittance on the transmission area TA may be further improved.

In exemplary embodiments, a deposition control layer 248 may be disposed on a portion of an insulating interlayer 236 on the transmission area TA. The deposition control layer 248 may have a non-light emitting property, and may also have an affinity and/or an adhesion for a conductive material, e.g., a metal lower than those of the display layer 260. In an exemplary embodiment, the deposition control layer 248 may include at least one of N,N′-diphenyl-N,N′-bis(9-phenyl-9H-carbazol-3-yl)biphenyl-4,4′-diamine, N(diphenyl-4-yl)9,9-dimethyl-N-(4(9-phenyl-9H-carbarzol-3-yl)phenyl)-9H-fluorene-2-amine, or 2-(4-(9,10-di(naphthalen-2-yl)anthracen-2-yl)phenyl)-1-phenyl-1H-benzo-[D]imidazole, etc., for example.

In exemplary embodiments, the second electrode 270 may be also disposed on a sidewall of the transmitting window 290a, on which the deposition control layer 248 is not provided.

An encapsulation layer 285 may cover the second electrode 275 and the deposition control layer 248, and may be commonly provided on the pixel area PA and the transmission area TA.

As described above, a colored polymer substrate may be employed as a base substrate to improve flexible and mechanical properties. Further, the color correction layer including the nano-pore array may be disposed on the colored polymer substrate to achieve a substantially transparent substrate. Further, the nano-pore array may be provided by a simple process using the block copolymer do that the transparent display device having an improved transmittance can be manufactured.

The embodiments may be applied to any display device having transparency and flexibility and any system including the display device. In an exemplary embodiment, the embodiments may be applied to various electronic devices such as a television, a computer monitor, a laptop, a digital camera, a cellular phone, a smart phone, a smart pad, a personal digital assistant (“PDA”), a portable multimedia player (“PMP”), a MP3 player, a navigation system, a head up display, a game console, a video phone, etc. The embodiments may be also applied to a wearable display device.

The foregoing is illustrative of exemplary embodiments, and is not to be construed as limiting thereof. Although a few exemplary embodiments have been described, those skilled in the art will readily appreciate that many modifications are possible in the exemplary embodiments without materially departing from the novel teachings and advantages of exemplary embodiments. Accordingly, all such modifications are intended to be included within the scope of exemplary embodiments as defined in the claims. In the claims, means-plus-function clauses are intended to cover the structures described herein as performing the recited function and not only structural equivalents but also equivalent structures. Therefore, it is to be understood that the foregoing is illustrative of exemplary embodiments and is not to be construed as limited to the specific embodiments disclosed, and that modifications to the disclosed exemplary embodiments, as well as other exemplary embodiments, are intended to be included within the scope of the appended claims. The invention is defined by the following claims, with equivalents of the claims to be included therein.

What is claimed is:

1. A transparent display device, comprising:
a polymer substrate including a pixel area and a transmission area;
a color correction layer including a metal nano-pattern on the polymer substrate;
a pixel circuit on the color correction layer;
a first electrode connected to the pixel circuit;
a display layer on the first electrode; and
a second electrode facing the first electrode and covering the display layer.

2. The transparent display device of claim 1, wherein the color correction layer is provided by a block copolymer.

3. The transparent display device of claim 1, wherein the color correction layer corrects a color of light transmitted from the polymer substrate.

4. The transparent display device of claim 1, wherein the metal nano-pattern includes a periodic nano-pore array.

5. The transparent display device of claim 4, wherein a width of each nano-pore included in the periodic nano-pore array is about 30 nanometers to about 50 nanometers.

6. The transparent display device of claim 4, wherein the metal nano pattern includes nano-cylinder structures substantially perpendicularly oriented to a surface of the polymer substrate.

7. The transparent display device of claim 1, wherein the color correction layer further includes at least one of gold (Au), silver (Ag), platinum (Pt), palladium (Pd), iridium (Ir), osmium (Os), ruthenium (Ru), and rhodium (Rh).

8. The transparent display device of claim 1, wherein the polymer substrate further includes a colored polymer material, and
wherein a surface plasmon resonance occurs in the metal nano-pattern such that the polymer substrate becomes substantially colorless and transparent.

9. The transparent display device of claim 8, wherein the colored polymer material includes a polyimide-based material.

10. The transparent display device of claim 1, further comprising:
a barrier layer is between the polymer substrate and the color correction layer.

11. The transparent display device of claim 1, further comprising:
a barrier layer is between the color correction layer and the pixel circuit.

12. A transparent display device, comprising:
a transparent flexible substrate including a pixel area and a transmission area;
a color correction layer, which includes a metal nano-pore array, on the transparent flexible substrate;
a barrier layer on the color correction layer;
a pixel circuit selectively disposed on a portion of the barrier layer on the pixel area;
a circuit insulation layer which at least partially covers the pixel circuit on the barrier layer;
a via-insulation layer covering the pixel circuit on the circuit insulation layer;
a first electrode on the via-insulation layer, the first electrode being electrically connected to the pixel circuit;
a display layer on the first electrode; and
a second electrode facing the first electrode and covering the display layer.

13. The transparent display device of claim 12, wherein the transparent flexible substrate further includes a colored polymer material, and
wherein the color correction layer is provided by a block copolymer.

14. The transparent display device of claim 12, wherein the via-insulation layer is disposed only on the pixel area.

15. The transparent display device of claim 14, further comprising:
a pixel defining layer on the via-insulation layer, the pixel defining layer exposing a top surface of the first electrode,
wherein a transmitting window is defined in the transmission area by sidewalls of the pixel defining layer and the via-insulation layer.

16. The transparent display device of claim 15, wherein the circuit insulation layer includes a gate insulation layer and an insulating interlayer sequentially stacked on the barrier layer,
wherein the gate insulation layer and the insulating interlayer extend commonly on the pixel area and the transmission area, and
wherein a top surface of the insulating interlayer is exposed by the transmitting window.

17. A method of manufacturing a transparent display device, comprising:
forming a color correction layer including a metal nano-pore array including a metal nano-pattern on a colored polymer substrate;
forming a pixel circuit on the color correction layer;
forming an insulation structure covering the pixel circuit; and
forming a display structure on the insulation structure such that the display structure is electrically connected to the pixel circuit.

18. The method of claim 17, wherein a surface plasmon resonance occurs in the metal nano-pattern such that the colored polymer substrate becomes substantially colorless and transparent.

19. The method of claim 17, wherein forming the color correction layer includes:
forming a metal thin film on the colored polymer substrate;
forming a copolymer thin film on the metal thin film;
micro-phase separating the copolymer thin film to a block copolymer including nano-cylinder structures substantially perpendicularly oriented to a surface of the colored polymer substrate;
exposing the metal thin film by partially removing the block copolymer such that the metal thin film becomes the metal nano-pore array;
etching exposed portions of the metal thin film; and
removing remaining portions of the block copolymer on the metal thin film.

20. The method of claim 19, wherein the block copolymer includes polystyrene-block-poly(methyl methacrylate) (PS-b-PMMA).
